(19) United States
(12) Patent Application Publication
(10) Pub. No.: US 2009/0260860 A1
(43) Pub. Date: Oct. 22, 2009

(54) FLEXIBLE PRINTED CIRCUIT BOARD

(75) Inventors: YU-CHANG PAI, Tu-Cheng (TW); SHOU-KUO HSU, Tu-Cheng (TW); CHIEN-HUNG LIU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/211,057

(22) Filed: Sep. 15, 2008

(30) Foreign Application Priority Data
Apr. 18, 2008 (CN) 200810301209.6

(51) Int. Cl. H05K 1/02; H05K 3/46

(52) U.S. Cl. 174/254; 29/847

(57) ABSTRACT

An exemplary FPCB includes two or more dielectric layers. Each dielectric layer is located between a signal layer and a ground layer. A differential pair including two transmission lines is arranged in each signal layer. Each ground layer includes one or more voids defined therein. Each void is opposite and adjacent to a differential pair.

### CROSS-REFERENCES TO RELATED APPLICATION

Relevant subject matter is disclosed in a co-pending U.S. Patent Application entitled “FLEXIBLE PRINTED CIRCUIT BOARD”, filed on Nov. 29, 2007 with application Ser. No. 11/946,859, and assigned to the same assignee as this application.

### BACKGROUND

1. Field of the Invention

The present invention relates to a flexible printed circuit board (FPCB), and particularly to an FPCB for transmitting high speed signals.

2. Description of Related Art

FPCBs are light, soft, thin, small, ductile, flexible and support high wiring density. FPCBs can be three-dimensionally wired and shaped according to space limitations. Flexible circuits are useful for electronic packages where flexibility, weight control and the like are important.

Referring to FIG. 3, a conventional FPCB, according to the prior art, includes a signal layer and a ground layer 50. A differential pair 51 consisting of two transmission lines 52 and 54 is arranged in the signal layer. The ground layer is formed vertically beneath the signal layer and etched in a grid array. Because the layout in the ground layer 50 vertically beneath the transmission line 52 is different from that beneath the transmission line 54, noise is easily generated, which prevents the FPCB transmitting high speed signals.

What is needed, therefore, is a FPCB which can transmit high speed signals with less noise.

### BRIEF DESCRIPTION OF THE DRAWINGS

FIG. 1 is a cross-sectional view of an FPCB according to an embodiment of the present invention;

FIG. 2 is a cross-sectional view of an FPCB according to a second embodiment of the present invention; and

FIG. 3 is a schematic diagram of a conventional FPCB according to the prior art.

### DETAILED DESCRIPTION

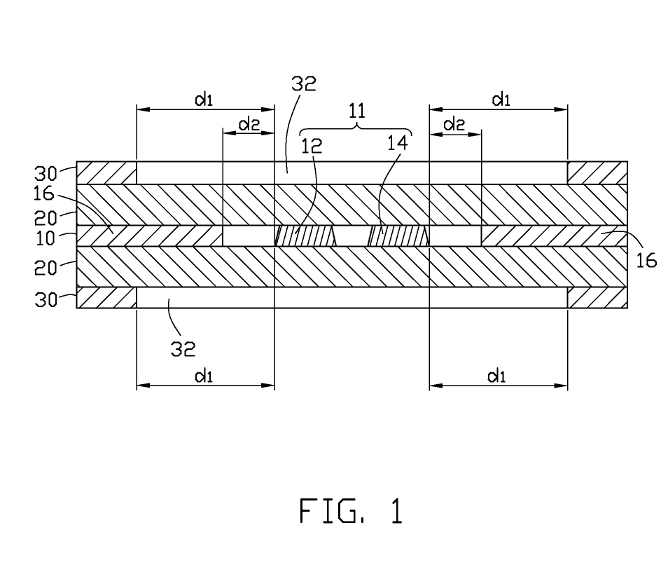

Referring to FIG. 1, an FPCB in accordance with an embodiment of the present invention includes a signal layer 10, two ground layers 30, and two dielectric layers 20. The signal layer 10 is between the two ground layers 30. Between the signal layer 10 and each of the two ground layers 30 are a corresponding one of the two dielectric layers 20. A differential pair 11 consisting of two transmission lines 12, 14 is arranged in the signal layer 10. The ground layers 30 are covered with conductive material, such as copper. A void 32 is defined in each ground layer 30 opposite to the transmission lines 12 and 14. Each void 32 is formed by cutting away the conductive materials opposite to the corresponding transmission lines 12 and 14. Thus, the problem of low characteristic impedance of the transmission lines 12 and 14, which is caused by a distance between the differential pair 11 and each ground layer 30 being too short, is avoided. There is a horizontal distance d1 between each edge of each void 32 and its nearest transmission line. Two sheets 16 made of conductive material, such as copper, are respectively arranged at opposite sides of the differential pair 11 and parallel to the transmission lines 12 and 14, and coupled to ground. There is a horizontal distance d2 between each sheet 16 and its nearest transmission line.

The length of the horizontal distances d1 and d2 are obtained by simulating the FPCB of FIG. 1 in a conventional simulation software, simulating the signal type to be transmitted through the transmission lines 12 and 14 and the desired impedance of the transmission line, and adjusting the horizontal distances d1 and d2, until desired characteristic impedances of the transmission lines 12 and 14 are achieved. The distance d1 and d2 are also affected by the following factors: the width of each transmission line 12, 14; a distance between the transmission line 12 and 14; widths of the sheets 16; and the height of the dielectric layers 20.

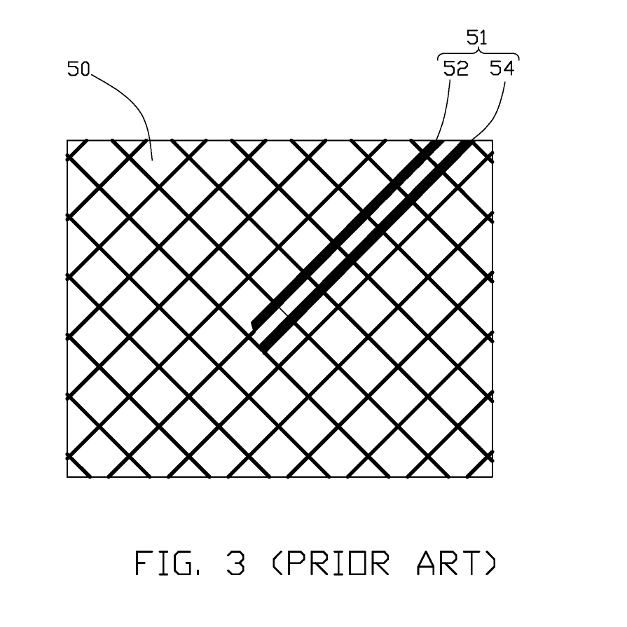

The layout of each of the two ground layers opposite the transmission line 12 and 14 are the same, and the noise caused by the grid array construction of the ground layer in FIG. 3 is reduced, and the impedance of the transmission line is matched, so the FPCB of the embodiment of the present invention can transmit high speed signals with little noise.

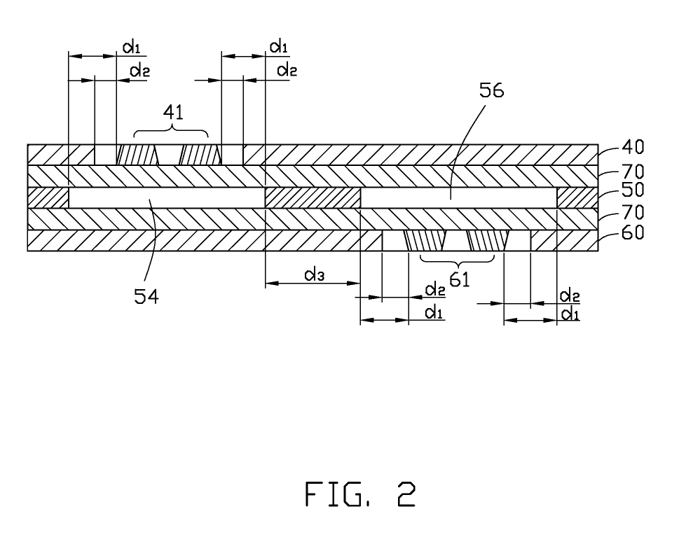

Referring to FIG. 2, in another embodiment, an FPCB includes two signal layers 40 and 60, a ground layer 50 lying between the two signal layers 40 and 60, and a dielectric layer 70 between the ground layer 50 and each of the two signal layers 40 and 60. First and second differential pairs 41 and 61 are arranged in the two signal layers 40 and 60 respectively. First and second voids 54 and 56 are defined in the ground layer 50 opposite to the differential pairs 41 and 61 respectively. A distance d3 between the two facing edges of the first and second voids 54 and 56 is greater than or equal to thrice the thickness of each dielectric layer 70. Therefore, noise of the transmission lines of the first and second differential pairs 41 and 61, which is caused by an influence of the first void 54 on the second differential pair 61, or an influence of the second void 56 on the first differential pair 41, is avoided.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A flexible printed circuit board comprising:
two or more dielectric layers; each dielectric layer is located between a signal layer and a ground layer;
a differential pair comprising of two transmission lines arranged in each signal layer;
wherein each ground layer has one or more voids defined therein, each void is opposite and adjacent to a differential pair.

2. The flexible printed circuit board as claimed in claim 1, wherein each signal layer comprises two sheets made of conductive materials arranged at opposite sides of each differential pair, and the sheets are apart from and parallel to the transmission lines.

3. The flexible printed circuit board as claimed in claim 2, wherein the sheets are made of copper.

4. The flexible printed circuit board as claimed in claim 2, wherein each sheet has the same length as the transmission lines.

5. The flexible printed circuit board as claimed in claim 1, wherein there is a first predetermined distance from each edge of each void to the adjacent transmission line to the edge, and a second predetermined distance from each sheet to the adjacent transmission line to the sheet.

6. The flexible printed circuit board as claimed in claim 1, comprises two ground layers and a signal layer.

7. The flexible printed circuit board as claimed in claim 1, comprises two signal layers and a ground layer.

8. The flexible printed circuit board as claimed in claim 7, wherein the ground layer defines two voids, the distance between two adjacent edges of the two voids is greater than thrice the thickness of each dielectric layer.

9. The flexible printed circuit board as claimed in claim 7, wherein the ground layer defines two voids, the distance between two adjacent edges of the two voids is equal to thrice the thickness of each dielectric layer.

10. A method for making a flexible printed circuit board, comprising:
providing two or more dielectric layers;
locating each dielectric layer between a signal layer and a ground layer;
arranging a differential pair comprising of two transmission lines in each signal layer; and
removing material from a conductive material in each ground layer, the removal occurs opposite and adjacent to a differential pair.

11. The method as claimed in claim 10, further comprising:
placing two sheets made of conductive transmission lines at opposite sides of each differential pair in each signal layer; the two sheets being apart from and parallel to the transmission lines.

12. The method as claimed in claim 1, wherein each sheet has the same length as the transmission lines.

13. The method as claimed in claim 1, wherein the sheets are made of copper.

14. The method as claimed in claim 10, further comprising:
providing a simulation software;
simulating the flexible printed circuit by the simulation software to obtain a distance from each edge of each void to the nearest transmission line to the edge, and a distance from each sheet to the nearest transmission line to the sheet.

15. The method as claimed in claim 10, wherein the providing comprises providing two ground layers; and locating a signal layer between the two ground layers.

16. The method as claimed in claim 10, wherein the providing comprises providing two signal layers; and locating a ground layer between the two signal layers.

17. The method as claimed in claim 16, wherein the removing comprises cutting away two sections of the conductive material in the ground layer; and the distance between two adjacent edges of the two sections is greater than thrice the thickness of each dielectric layer.

18. The method as claimed in claim 16, wherein the removing comprises cutting away two sections of the conductive material in the ground layer; and the distance between two adjacent edges of the two sections is equal to thrice the thickness of each dielectric layer.
